(19) United States
(12) Patent Application Publication
(10) Pub. No.: US 2023/0266659 A1
(43) Pub. Date: Aug. 24, 2023

(54) OPC Method

(71) Applicant: Shanghai Huali Integrated Circuit Corporation, Shanghai (CN)

(72) Inventor: Xinxin Fu, Shanghai (CN)

(73) Assignee: Shanghai Huali Integrated Circuit Corporation, Shanghai (CN)

(21) Appl. No.: 18/154,154

(22) Filed: Jan. 13, 2023

(30) Foreign Application Priority Data
Feb. 21, 2022 (CN) 20221015485.1

(51) Int. Cl. G03F 1/36

(52) U.S. Cl. CPC G03F 1/36

(57) ABSTRACT

The present application discloses an OPC method, which includes: step 1: providing an initial target layer and setting a mask minimum resolution dimension; step 2: selecting a first pattern that will violate a mask rule check in subsequent MBOPC from the initial target layer; step 3: performing split processing on the first pattern to divide each side of the first pattern into a plurality of splits including corner splits and a middle split, the initial target layer after split processing being a second target layer; and step 4: performing MBOPC based on the second target layer and obtaining a mask pattern layer, the corner splits and the middle splits being corrected separately, the corner dimension of the first pattern in the mask pattern layer being controlled through the corner splits, the area of the first pattern in the mask pattern layer being controlled through the middle split.

### CROSS-REFERENCE TO RELATED APPLICATIONS

This application claims priority to Chinese patent application No. CN 202210154850.1, filed on Feb. 21, 2022, the disclosure of which is incorporated herein by reference in its entirety.

### TECHNICAL FIELD

The present application relates to a semiconductor integrated circuit manufacturing method, in particular to an Optical Proximity Correction (OPC) method.

### BACKGROUND

With the reduction of semiconductor manufacturing process nodes, the critical dimension of the pattern is close to the lithography limit, the structure of the pattern is relatively more complex, and the mask correction is facing a huge challenge. In the exposure of lithography, due to the interference and diffraction effects of light, the exposed pattern will have the problem of distortion, including corner rounding, line end shortening, etc. Optical Proximity Correction (OPC) has become an indispensable process in the integrated circuit (IC). Through model simulation, the predicted contour is infinitely close to the target value. When running OPC, we need set mask rule constraint (MRC) including mask line and space, that is, the minimum resolution dimension of mask. The edge will not move until it approaches the rule of minimum cd and space to avoid violating the MRC. The set rule of MRC is generally determined by the process node and the process capacity of the mask shop, which is determined by the mask manufacturing resolution

For lower process nodes, in addition to changes in conventional exposure conditions, errors caused by mask manufacturing differences are particularly important. If there is an MRC problem, there is open and short risk, and the lithography process window is small. Via layer plays a role of connection in the IC and it is the channel connecting the below and above metal layers. The staggered structure is very common in the via layer. Generally, the corner-to-corner space is very small, and the MRC problem is often encountered in OPC.

The existing OPC methods will be described as follows with reference to the drawings:

Referring to FIG. 1, it illustrates a flowchart of an existing OPC method. The existing OPC method includes the following steps:

In step S101, an initial layout is provided. In FIG. 1, Drawn represents the initial layout, which is formed by drawing a circuit.

In step S102, rule-based OPC is performed on the initial layout to obtain a target layer. In FIG. 1, the target layer is also represented as Target.

Referring to FIG. 2A, it illustrates a schematic diagram of a pattern structure of a target layer in the existing OPC method. The target layer 201 includes a cluster of patterns 202. The patterns 202 in FIG. 2A are square, and an array structure formed through the arrangement of the patterns 202 is a dense stagger pattern. In the dense stagger pattern, diagonals of each pattern 202 are aligned and arranged periodically. The minimum space between the patterns 202 is corner-to-corner space d201, that is, the distance between adjacent corners of two adjacent patterns 202. The pitch of the patterns 202 is equal to a sum of the length of the diagonal of the pattern and the minimum space between the patterns. Generally, the via layer pattern adopts square patterns 202 and a dense stagger pattern.

In step S103, model-based OPC is performed based on the target layer and a mask pattern layer is obtained. The mask pattern layer in FIG. 1 is also represented by Mask. The model-based OPC includes several iterations of mask correction.

Referring to FIG. 2B, it illustrates a schematic diagram of a pattern structure of a mask pattern layer formed in the existing OPC method. Patterns 204 of a mask pattern layer 203 correspond to the patterns 202 in FIG. 2A, and the patterns 204 are obtained by performing several iterations of mask corrections on the patterns 202.

In step S104, an MRC is performed. In FIG. 1, the MRC is also represented by MRC. The MRC needs to ensure that the critical dimension and corner-to-corner space between the patterns 204 of the mask pattern layer 203 in FIG. 2B meet the mask minimum resolution dimension specified by the MRC.

Step S104 may be inserted into each iterative cyclic operation of Model-Based OPC (MBOPC). When the critical dimension and corner-to-corner space between the patterns 204 are close to the critical dimension minimum resolution value and the space minimum resolution value, the edge will not move any longer to avoid violating the MRC. It can be seen from FIG. 2A that in the dense stagger pattern, the corner-to-corner space d201 of the patterns 202 is small. Thus, in the MBOPC, it is easy to occur in FIG. 2B that the corner-to-corner space between the patterns 204 is close to the space minimum resolution value. At this time, all edges of the patterns 204 will stop moving, the MBOPC will stop, and the via open defect of the pattern 204 easily occurs. When the area of the pattern 204 is insufficient, the area and cd of the exposed mask of the pattern 204 will be very small. The contour 205 in FIG. 2B is a schematic diagram of a simulation pattern of an exposed pattern of the pattern 204. It can be seen that both the area and cd of the contour 205 are small, which will be greatly different from the target pattern 202 in FIG. 2A, and an off-target defect will appear.

### BRIEF SUMMARY

According to some embodiments in this application,

the OPC method provided by the present application includes the following steps:

step 1: providing an initial target layer and setting a mask minimum resolution dimension;

step 2: selecting a first pattern that will violate a mask rule check in subsequent Model-Based OPC (MBOPC) from the initial target layer according to the mask minimum resolution dimension;

step 3: performing split processing on the first pattern, the split processing dividing each side of the first pattern into a plurality of splits, the splits of each side including corner splits and a middle split, one vertex of each corner split being a vertex of the side, the other vertex of each corner split being a vertex of the adjacent middle split, the initial target layer after split processing being a second target layer; and

step 4: performing model-based OPC based on the second target layer and obtaining a mask pattern layer, the model-based OPC including several iterations, the corner splits and the middle split of each side of the first pattern being corrected separately in each iteration, the corner dimension of the first pattern in the mask pattern layer being controlled through the corner splits, the area of the first pattern in the mask pattern layer being controlled through the middle split.

In some cases, after step 4, the OPC method further includes:

step 5: performing the mask rule check on the mask pattern layer.

In some cases, in step 1, the initial target layer is obtained through rule-based OPC of an initial layout.

In some cases, the mask minimum resolution dimension includes a critical dimension minimum resolution value and a space minimum resolution value.

In some cases, in step 5, when the critical dimension of the first pattern in the mask pattern layer is more than the critical dimension minimum resolution value and the space is more than the space minimum resolution value, the mask rule checks passes.

In some cases, the first pattern includes a square hole pattern.

In some cases, the square hole pattern includes a via layer pattern.

In some cases, in the initial target layer, an array structure formed through arrangement of each first pattern is a dense stagger pattern; in the dense stagger pattern, diagonals of each first pattern are aligned and arranged periodically, the minimum space between the first patterns is equal to a distance between adjacent corners of two adjacent first patterns, and the pitch of the first patterns is equal to a sum of the length of the diagonal of the first pattern and the minimum space.

In some cases, the mask minimum resolution dimension is determined by a process node and mask manufacturing capacity.

In some cases, the critical dimension minimum resolution value and the space minimum resolution value are 18 nm or 12 nm at the same time.

In some cases, the minimum space between the first patterns is less than 20 nm, and the pitch of the first patterns is less than 115 nm.

In some cases, a target value of the side length of the first pattern is 68 nm and the dimension of the corner split in the split processing is 5-20 nm.

In some cases, in step 3, the split processing divides each side of the first pattern into three splits, and the three splits includes two corner splits and a middle split.

However, in the prior art, since the sides of the first pattern are not subjected to split processing before MBOPC, when the corner-to-corner space between the first patterns violates the limit of the MRC and the iterative cyclic operation is stopped during MBOPC, the area of the first pattern will remain small, and finally the contour of the first pattern after MBOPC, that is, the simulation pattern of the exposed pattern, is caused to have a off-target defect. After providing the initial target layer in the present application, the MBOPC is not directly performed based on the initial target layer, but the first pattern that will violate the MRC in the MBOPC is selected according to the characteristics of the pattern in the initial target layer. Then, split processing is performed on the selected pattern and the second target layer is formed. Then, the MBOPC is performed. After each side of the first pattern is subjected to the split processing, the corner split and the middle split can be corrected separately in each iterative cyclic operation of the MBOPC, so that the corner dimension of the first pattern and the dimension of the middle area can be adjusted separately. By adjusting the corner dimension of the first pattern, the corner-to-corner space between the first patterns does not violate the MRC. By adjusting the dimension of the middle area, the area of the first pattern can be adjusted, so that the area of the first pattern can be increased when the corner-to-corner space between the first patterns meets the requirement of the MRC. The increase of the area of the first pattern after the MBOPC can make the contour be on target, so that the pattern after actual exposure will also be on target.

The present application is particularly applicable to the OPC of square patterns in a dense stagger pattern, such as the via layer pattern, and can realize the dimension of the square patterns on the mask pattern layer. Under the condition of not violating the MRC, not only the simulation contour of the exposed pattern is on target, but also the process variation band (pvband) and mask error enhancement factor (meef) under the Process Window (PW) meet the requirements of mass production.

### BRIEF DESCRIPTION OF THE DRAWINGS

The present application will be further described below in detail in combination with the specific embodiments with reference to the drawings.

FIG. 1 illustrates a flowchart of an existing OPC method.

FIG. 2A illustrates a schematic diagram of a pattern structure of a target layer in an existing OPC method.

FIG. 2B illustrates a schematic diagram of a pattern structure of a mask pattern layer formed by adopting an existing OPC method.

FIG. 3 illustrates a flowchart of an OPC method according to an embodiment of the present application.

FIG. 4A illustrates a schematic diagram of a pattern structure of an initial target layer in an OPC method according to an embodiment of the present application.

FIG. 4B illustrates a schematic diagram of a pattern structure of a second target layer in an OPC method according to an embodiment of the present application.

FIG. 4C illustrates a schematic diagram of a pattern structure of a mask pattern layer in an OPC method according to an embodiment of the present application.

FIG. 4D illustrates a schematic diagram of a contour formed through exposed pattern simulation by adopting the mask pattern layer in FIG. 4C.

FIG. 5A illustrates a simulation pattern of a mask pattern layer and a contour formed by adopting an existing OPC method.

FIG. 5B illustrates a simulation pattern of a mask pattern layer and a contour formed when a corner split dimension is 5 nm in an OPC method according to an embodiment of the present application.

FIG. 5C illustrates a simulation pattern of a mask pattern layer and a contour formed when a corner split dimension is 10 nm in an OPC method according to an embodiment of the present application.

FIG. 5D illustrates a simulation pattern of a mask pattern layer and a contour formed when a corner split dimension is 15 nm in an OPC method according to an embodiment of the present application.

FIG. 5E illustrates a simulation pattern of a mask pattern layer and a contour formed when a corner split dimension is 20 nm in an OPC method according to an embodiment of the present application.

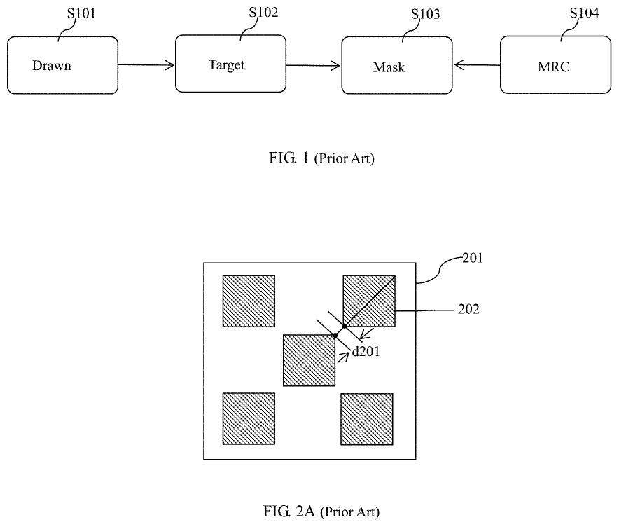

### DETAILED DESCRIPTION

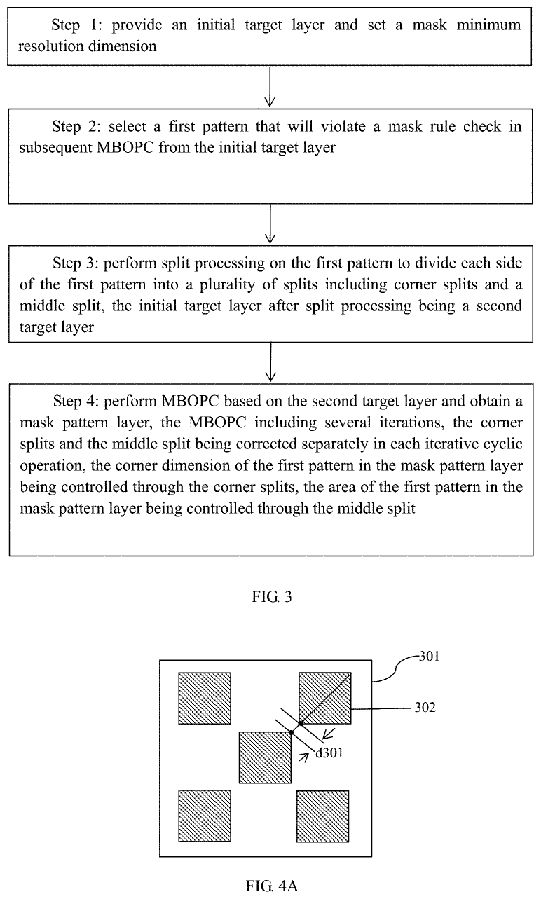

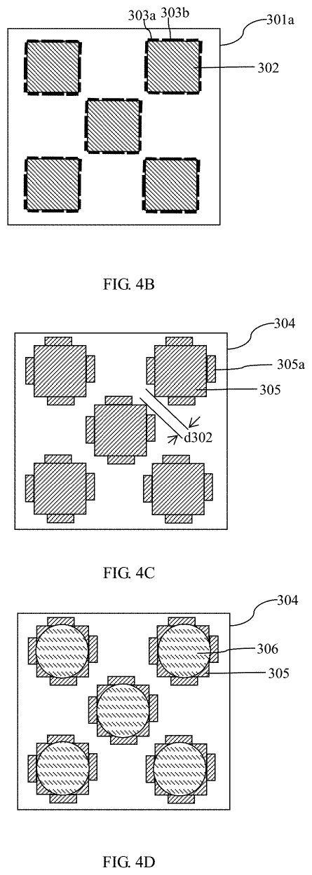

Referring to FIG. 3, it illustrates a flowchart of an OPC method according to an embodiment of the present application. Referring to FIG. 4A, it illustrates a schematic diagram of a pattern structure of an initial target layer 301 in an OPC method according to an embodiment of the present application. Referring to FIG. 4B, it illustrates a schematic diagram of a pattern structure of a second target layer 301a in an OPC method according to an embodiment of the present application. Referring to FIG. 4C, it illustrates a schematic diagram of a pattern structure of a mask pattern layer 304 in an OPC method according to an embodiment of the present application. Referring to FIG. 4D, it illustrates a schematic diagram of a contour formed through exposed pattern simulation by adopting the mask pattern layer 304 in FIG. 4C. The OPC method provided by the present application includes the following steps:

In step 1, referring to FIG. 4A, an initial target layer 301 is provided and a mask minimum resolution dimension is set.

In the embodiment of the present application, the initial target layer 301 is obtained through rule-based OPC of an initial layout.

The mask minimum resolution dimension includes a critical dimension minimum resolution value and a space minimum resolution value.

The mask minimum resolution dimension is determined by a process node and mask manufacturing capacity.

In some embodiments, and the critical dimension minimum resolution value and the space minimum resolution value are 18 nm or 12 nm at the same time.

In step 2, a first pattern 302 that will violate a mask rule check in subsequent model-based OPC is selected from the initial target layer 301 according to the mask minimum resolution dimension. FIG. 4A shows only the first pattern 302 in the initial target layer 301. The initial target layer 301 also includes other types of patterns, which are not illustrated in FIG. 4A.

In the embodiment of the present application, the first pattern 302 includes a square hole pattern.

In some preferred embodiments, the square hole pattern includes a via layer pattern.

In the initial target layer 301, an array structure formed through arrangement of each first pattern 302 is a dense stagger pattern; in the dense stagger pattern, diagonals of each first pattern 302 are aligned and arranged periodically, the minimum space between the first patterns 302 is equal to a distance between adjacent corners of two adjacent first patterns 302, and the pitch of the first patterns 302 is equal to a sum of the length of the diagonal of the first pattern 302 and the minimum space.

In some embodiments, the minimum space between the first patterns 302 is less than 20 nm and the pitch of the first patterns 302 is less than 115 nm.

In step 3, referring to FIG. 4B, split processing is performed on the first pattern 302. The split processing divides each side of the first pattern 302 into a plurality of splits. The splits of each side include corner splits 303a and middle splits 303b. One vertex of each corner split 303a is a vertex of the side. The other vertex of each corner split 303a is a vertex of the adjacent middle splits 303b. The broken line between the corner split 303a and the middle splits 303b in FIG. 4B is only used for visually distinguishing the corner split 303a and the middle splits 303b. In fact, the corner split 303a and the middle splits 303b are connected together.

The initial target layer 301a after split processing is a second target layer 301a.

In the embodiment of the present application, the split processing divides each side of the first pattern 302 into three splits, and the three splits includes two corner splits 303a and one middle split 303b.

In some embodiment, a target value of the side length of the first pattern 302 is 68 nm and the dimension of the corner split 303a in the split processing is 5-20 nm.

In step 4, referring to FIG. 4C, model-based OPC is performed based on the second target layer 301a and a mask pattern layer 304 is obtained. The model-based OPC includes a plurality of iterative cyclic operations. The corner splits 303a and the middle split 303b of each side of the first pattern 302 are corrected separately in each iterative cyclic operation. The corner dimension of the first pattern 305 in the mask pattern layer 304 is controlled through the corner splits 303a. The area of the first pattern 305 in the mask pattern layer 304 is controlled through the middle splits 303b. In FIG. 4C, the first pattern is separately represented by reference sign 305. The first pattern 305 in FIG. 4C is formed by the first pattern 302 in FIG. 4A after MBOPC. It can be seen from FIG. 4C that the separate correction of the corner splits 303a and the middle split 303b of each side of the first pattern 302 can avoid that each side of the first pattern 302 needs to be moved as a whole in the process of MBOPC in the existing method, so that it can be moved in splits. In this way, the movement amount of the side of the first pattern 302 at the corner splits 303a is different from the movement amount at the middle splits 303b. By comparing with the first pattern 302 in the initial target layer 301 in FIG. 4A, it can be seen that the side of the first pattern 305 in FIG. 4C after MBOPC is no longer flat, a convex pattern 305a is formed at the corresponding position of the middle splits 303b, and the convex pattern 305a will increase the area of the first pattern 305.

In step 5, the mask rule check is performed on the mask pattern layer 304.

In step 5, when the critical dimension of the first pattern 305 in the mask pattern layer 304 is more than the critical dimension minimum resolution value and the space is more than the space minimum resolution value, the mask rule checks passes.

Referring to FIG. 4C, the critical dimension of the first pattern 305 is the minimum width, and the space between the first patterns 305 is corner-to-corner space d302.

The mask rule check will be inserted into each iteration of model-based OPC. Even when the corner-to-corner space d302 is close to the space minimum resolution value, the side at the middle splits 303b can still be corrected, that is, moved, thus avoiding the defect that the entire side cannot be moved when the corner-to-corner space d302 is close to the space minimum resolution value in the existing method. The side movement at the middle splits 303b can increase the area of the first pattern 305, so the embodiment of the present application can increase the area of the first pattern 305 under the condition that the corner-to-corner space d302 does not violate MRC.

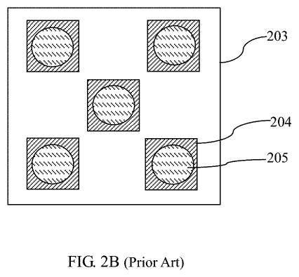

The increase of the area of the first pattern 305 can increase the area of the corresponding exposed pattern, so that the exposed pattern conforms to the target value, that is, on-target. As illustrated in FIG. 4D, the contour 306 is a schematic diagram of the simulation pattern of the exposed pattern corresponding to the first pattern 305. Compared with the contour 205 of FIG. 2B, the contour 306 obtained in the embodiment of the present application has a larger area and is closer to the corresponding target pattern, thus eliminating the off-target defect corresponding to FIG. 2B.

However, in the prior art, since the sides of the first pattern 302 are not subjected to split processing before MBOPC, when the corner-to-corner space between the first patterns 302 is restricted from violating MRC in MBOPC and the iteration is stopped, the area of the first pattern 302 will remain small, and finally the contour of the first pattern 302 after MBOPC, that is, the simulation pattern of the exposed pattern, will be off target. After providing the initial target layer 301 in the embodiment of the present application, model-based OPC is not directly performed based on the initial target layer 301, but the first pattern 302 that will violate MRC in model-based OPC is selected according to the characteristics of the patterns in the initial target layer 301. After that, split processing is performed on the selected patterns the second target layer 301a is formed. Then, MBOPC is performed. After each side of the first pattern 302 is subjected to split processing, the corner splits 303a and the middle splits 303b can be corrected separately in each iterative cyclic operation of MBOPC, so that the corner dimension of the first pattern 302 and the dimension of the middle area can be adjusted separately. By adjusting the corner dimension of the first pattern 302, the corner-to-corner space between the first patterns 302 does not violate MRC. By adjusting the dimension of the middle area, the area of the first pattern 302 can be adjusted, so that the area of the first pattern 302 can be increased when the corner-to-corner space between the first patterns 302 meets the requirements of MRC. The increase of the area of the first pattern 302 after MBOPC can make the contour be on target, so that the pattern after actual exposure will also be on target.

The present application is particularly applicable to the OPC of square patterns in a dense stagger pattern, such as the via layer pattern, and can realize the dimension of the square patterns on the mask pattern layer 304. Under the condition of not violating the MRC, not only the simulation contour of the exposed pattern is on target, but also the pvband and meef under the PW meet the requirements of mass production.

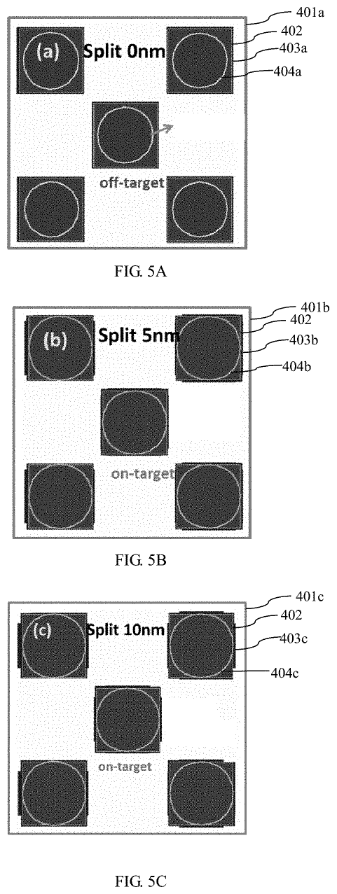

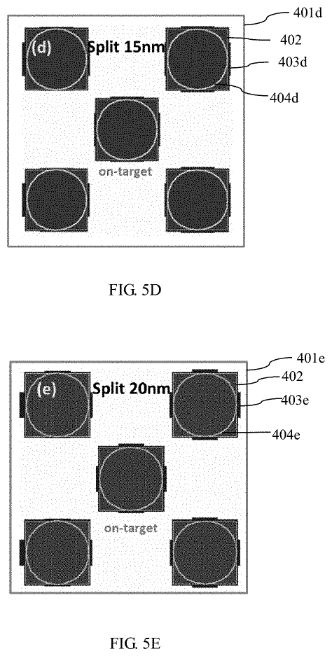

Referring to FIG. 5A, it illustrates a simulation pattern of a mask pattern layer and a contour formed by adopting an existing OPC method. A mask pattern layer 401a includes a mask pattern 403a for performing MBOPC on a target pattern 402. The target pattern 402 corresponds to the pattern 202 in FIG. 2A, and the mask pattern 403a corresponds to the pattern 204 in FIG. 2B. The existing method is also equivalent to that the dimension of the corner split described in the embodiment method of the present application is 0 nm, i.e., Split 0 nm. A contour 404a is a simulation pattern of the exposed pattern corresponding to the mask pattern 403a. It can be seen that the contour 404a is greatly different from the target pattern 402 and is in an off-target state.

FIG. 5B illustrates a simulation pattern of a mask pattern layer and a contour formed when a corner split dimension is 5 nm in an OPC method according to an embodiment of the present application. A mask pattern layer 401b includes a mask pattern 403b for performing MBOPC on a target pattern 402. The target pattern 402 corresponds to the pattern 302 in FIG. 4A, which is the same as the target pattern 402 in FIG. 5A. That is, different MBOPC operations are performed on the corresponding target patterns 402 to compare the correction results. A contour 404b is a simulation pattern of the exposed pattern corresponding to the mask pattern 403b. The dimension of the corner split in FIG. 5B is 5 nm, i.e., Split 5 nm. It can be seen that the contour 404b is close to the target pattern 402 and is in an on-target state.

FIG. 5C illustrates a simulation pattern of a mask pattern layer and a contour formed when a corner split dimension is 10 nm in an OPC method according to an embodiment of the present application. A mask pattern layer 401c includes a mask pattern 403c for performing MBOPC on a target pattern 402. The target pattern 402 corresponds to the pattern 302 in FIG. 4A. A contour 404c is a simulation pattern of the exposed pattern corresponding to the mask pattern 403c. The dimension of the corner split in FIG. 5C is 10 nm, i.e., Split 10 nm. It can be seen that the contour 404c is close to the target pattern 402 and is in an on-target state.

FIG. 5D illustrates a simulation pattern of a mask pattern layer and a contour formed when a corner split dimension is 15 nm in an OPC method according to an embodiment of the present application. A mask pattern layer 401d includes a mask pattern 403d for performing MBOPC on a target pattern 402. The target pattern 402 corresponds to the pattern 302 in FIG. 4A. A contour 404d is a simulation pattern of the exposed pattern corresponding to the mask pattern 403d. The dimension of the corner split in FIG. 5D is 15 nm, i.e., Split 15 nm. It can be seen that the contour 404d is close to the target pattern 402 and is in an on-target state.

FIG. 5E illustrates a simulation pattern of a mask pattern layer and a contour formed when a corner split dimension is 20 nm in an OPC method according to an embodiment of the present application. A mask pattern layer 401e includes a mask pattern 403e for performing MBOPC on a target pattern 402. The target pattern 402 corresponds to the pattern 302 in FIG. 4A. A contour 404e is a simulation pattern of the exposed pattern corresponding to the mask pattern 403e. The dimension of the corner split in FIG. 5E is 20 nm, i.e., Split 20 nm. It can be seen that the contour 404e is close to the target pattern 402 and is in an on-target state.

Test data corresponding to FIG. 5A to FIG. 5E are as shown in Table 1.

TABLE 1

| | Existing | | | | |
|---|---|---|---|---|---|
| | Method | Split processing | | | |
| Results | 0 nm | 5 nm | 10 nm | 15 nm | 20 nm |
| Target/nm | 67 | 67 | 67 | 67 | 67 |
| Mask Space/nm | 12.02 | 12.02 | 12.02 | 12.02 | 12.02 |
| Mask CD/nm | 70*69.1 | 71.4*71.5 | 71.7*71.9 | 73*73.2 | 74.3*74.4 |
| Mask Area/nm2 | 4837 | 5117 | 5177 | 5129 | 5122 |
| Contour/nm | 57.2 | 67.1 | 67.1 | 66.9 | 67 |
| PW_minCD/nm | 51.1 | 62.7 | 62.6 | 62.6 | 62.6 |
| Pvband/nm | 5.4 | 3.9 | 3.9 | 3.9 | 3.9 |
| Meef | 6.1 | 4.6 | 4.6 | 4.8 | 4.9 |

The split dimension corresponding to the existing method, i.e., the dimension of the corner split, is 0 nm. The split processing is listed according to different split dimensions, i.e., 5 nm, 10 nm, 15 nm and 20 nm.

In the test results, Target represents the critical dimension of the target pattern 402;

Mask Space represents the space between the mask patterns;

Mask CD represents the critical dimension of the mask patterns;

Mask Area represents the area of the mask patterns;

Contour represents the critical dimension of the contour;

PW_minCD represents the minimum critical dimension of the process window.

Pvband represents the process variation band.

Meef represents the mask error enhancement factor.

It can be seen that under the condition that Mask Space does not violate MRC, the corresponding Mask CD, Mask Area and critical dimension of Contour in the embodiment of the present application will increase, the PW_minCD will increase, the Pvband will decrease and the Meef will decrease, all of which indicate that the OPC results of the method according to the embodiment of the present application are better.

The present application has been described in detail through the specific embodiments above, which, however, do not constitute limitations to the present application. Without departing from the principle of the present application, those skilled in the art may make many changes and improvements, which should also be considered as included in the scope of protection of the present application.

What is claimed is:

1. An Optical Proximity Correction (OPC) method, comprising:
step 1: providing an initial target layer and setting a mask minimum resolution dimension;
step 2: selecting a first pattern that will violate a mask rule check in subsequent model-based OPC from the initial target layer according to the mask minimum resolution dimension;
step 3: performing split processing on the first pattern, the split processing dividing each side of the first pattern into a plurality of splits, the splits of each side comprising corner splits and a middle split, one vertex of each corner split being a vertex of the side, the other vertex of each corner split being a vertex of an adjacent middle split, the initial target layer after split processing being a second target layer; and
step 4: performing model-based OPC based on the second target layer and obtaining a mask pattern layer, the model-based OPC comprising several iterations, the corner splits and middle splits of each side of the first pattern being corrected separately in each iterative cyclic operation, a corner dimension of the first pattern in the mask pattern layer being controlled through the corner splits, an area of the first pattern in the mask pattern layer being controlled through the middle splits.

2. The OPC method according to claim 1, wherein, after step 4, the OPC method further comprises:
step 5: performing the mask rule check on the mask pattern layer.

3. The OPC method according to claim 1, wherein, in step 1, the initial target layer is obtained through rule-based OPC of an initial layout.

4. The OPC method according to claim 2, wherein the mask minimum resolution dimension comprises a critical dimension minimum resolution value and a space minimum resolution value.

5. The OPC method according to claim 4, wherein, in step 5, when a critical dimension of the first pattern in the mask pattern layer is more than the critical dimension minimum resolution value and a space is more than the space minimum resolution value, the mask rule check passes.

6. The OPC method according to claim 4, wherein the first pattern comprises a square hole pattern.

7. The OPC method according to claim 6, wherein the square hole pattern comprises a via layer pattern.

8. The OPC method according to claim 7, wherein, in the initial target layer, an array structure formed through arrangement of each first pattern is a dense stagger pattern; and in the dense stagger pattern, diagonals of each first pattern are aligned and arranged periodically, a minimum space between the first patterns is equal to a distance between adjacent corners of two adjacent first patterns, and a pitch of the first patterns is equal to a sum of a length of the diagonal of the first pattern and the minimum space.

9. The OPC method according to claim 8, wherein the mask minimum resolution dimension is determined by a process node and mask manufacturing capacity.

10. The OPC method according to claim 9, wherein the critical dimension minimum resolution value and the space minimum resolution value are 18 nm or 12 nm at the same time.

11. The OPC method according to claim 10, wherein the minimum space between the first patterns is less than 20 nm, and the pitch of the first patterns is less than 115 nm.

12. The OPC method according to claim 10, wherein a target value of a side length of the first pattern is 68 nm and a dimension of the corner split in the split processing is 5-20 nm.

13. The OPC method according to claim 8, wherein, in step 3, the split processing divides each side of the first pattern into three splits, and the three splits comprise two corner splits and one middle split.
